(19) United States
(12) Patent Application Publication
(10) Pub. No.: US 2024/0063043 A1
(43) Pub. Date: Feb. 22, 2024

(54) SEMICONDUCTOR MANUFACTURING APPARATUS AND METHOD OF FORMING SEMICONDUCTOR DEVICE

(71) Applicant: Taiwan Semiconductor Manufacturing Company, Ltd., Hsinchu (TW)

(72) Inventors: Yi-Jung CHEN, Yilan city (TW); Tsung-Fu TSAI, Changhua County (TW); Szu-Wei LU, Hsinchu City (TW); Chung-Shi LIU, Hsinchu city (TW)

(21) Appl. No.: 17/819,987

(22) Filed: Aug. 16, 2022

(51) Int. Cl. H01L 21/68; H01L 21/66; H01L 21/683

(52) U.S. Cl. CPC H01L 21/68; H01L 22/12; H01L 21/6838; H01L 2221/68372

(57) ABSTRACT

A method for forming a semiconductor device is provided. The method includes providing a wafer with multiple semiconductor dies on the adhesive film held by the frame element. The method also includes lifting a semiconductor die up from the wafer using an ejector element. The method includes picking up the semiconductor die with a collector element. The method further includes flip-chipping the semiconductor die with the collector element, and picking up the semiconductor die from the collector element using a bond-head element. In addition, the method includes measuring the warpage of the semiconductor die on the bond-head element using a sensor, then bonding the semiconductor die to a carrier using the bond-head element.

### BACKGROUND

In recent years, the semiconductor industry has experienced rapid growth due to continuous improvement in integration density of various electronic components, e.g., transistors, diodes, resistors, capacitors, etc. For the most part, this improvement in integration density has come from successive reductions in minimum feature size, which allows more components to be integrated into a given area. During the integration, the transportation of the devices and components has been developed.

Although existing semiconductor manufacturing apparatus and methods of fabricating semiconductor devices have generally been adequate for their intended purposes, they have not been entirely satisfactory in all respects.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1A to FIG. 1F are simplified perspective views showing different stages of a semiconductor die in a semiconductor manufacturing apparatus in accordance with some embodiments of the disclosure.

FIG. 2 through FIG. 11 are schematic cross-sectional views showing a method of using a semiconductor manufacturing apparatus during manufacturing a semiconductor device in accordance with some embodiments of the disclosure.

FIG. 12 illustrates a schematic view showing a plurality of measured points of the semiconductor die in accordance with some embodiments of the disclosure.

FIG. 13 illustrates a method of forming a semiconductor device in accordance with some embodiments of the disclosure.

FIG. 14 illustrates a method of forming a semiconductor device in accordance with some embodiments of the disclosure.

FIG. 15 illustrates a method of forming a semiconductor device in accordance with some embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first”, “second”, “third” and the like, may be used herein for ease of description to describe similar or different element(s) or feature(s) as illustrated in the figures, and may be used interchangeably depending on the order of the presence or the contexts of the description.

It should be appreciated that the following embodiment(s) of the disclosure provides applicable concepts that can be embodied in a wide variety of specific contexts. The specific embodiment(s) discussed herein is merely illustrative and is related to a semiconductor manufacturing apparatus and a method using the semiconductor manufacturing apparatus for manufacturing a semiconductor device, such as a semiconductor package or a semiconductor die (e.g., a system-on-integrated circuit (SoIC), or the like). In some embodiments, the semiconductor manufacturing apparatus includes a sensor that measures warpage after the semiconductor die is transferred to the bond-head element. The warpage measurement provides data to optimize the bonding parameters, so that the subsequent bonding process may be performed accurately, raising the yield.

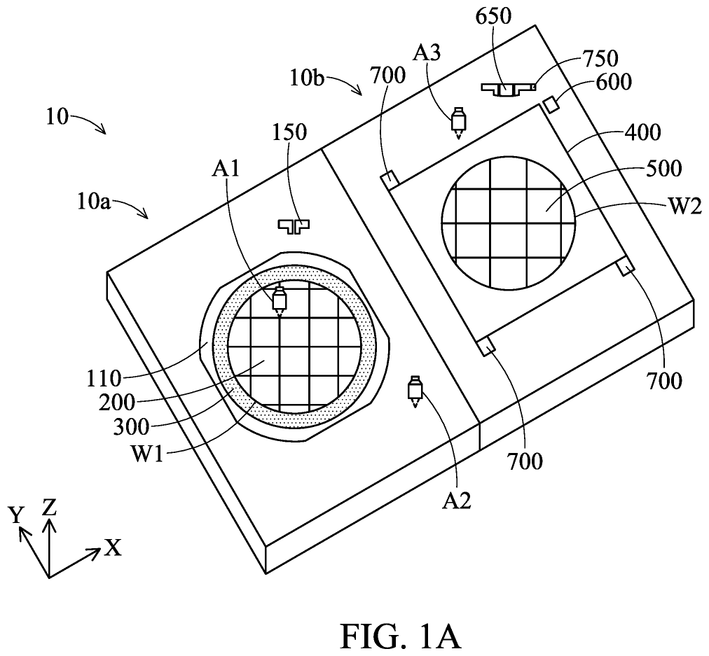

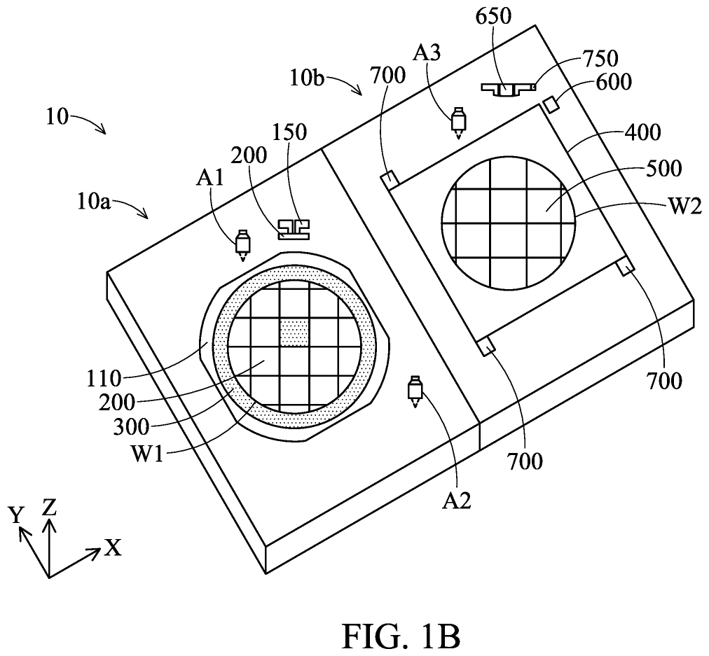

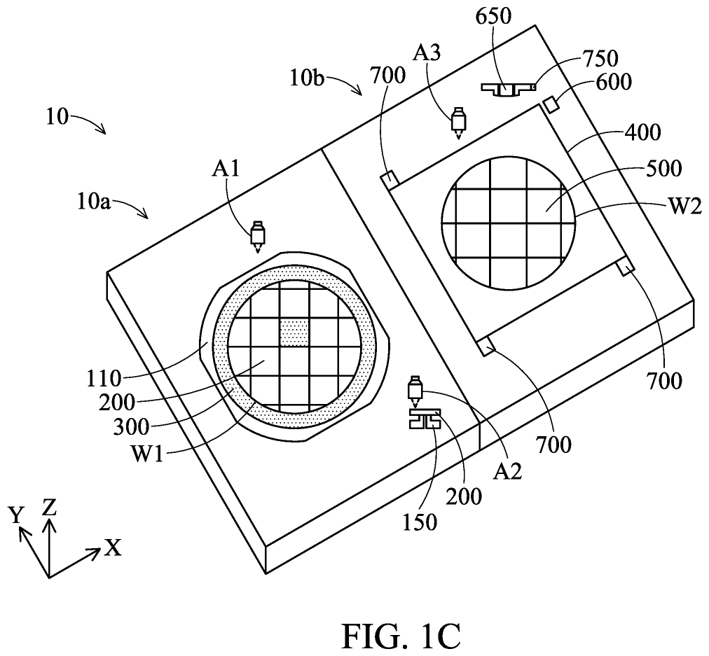

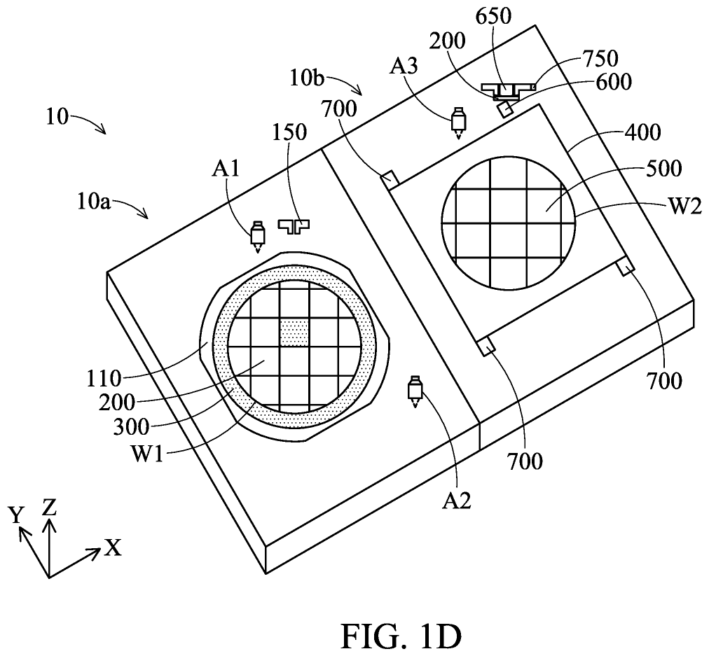

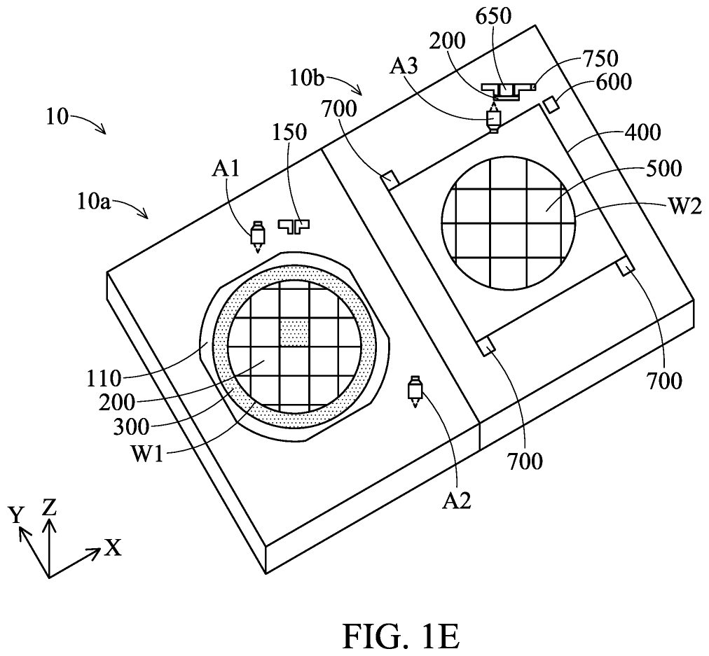

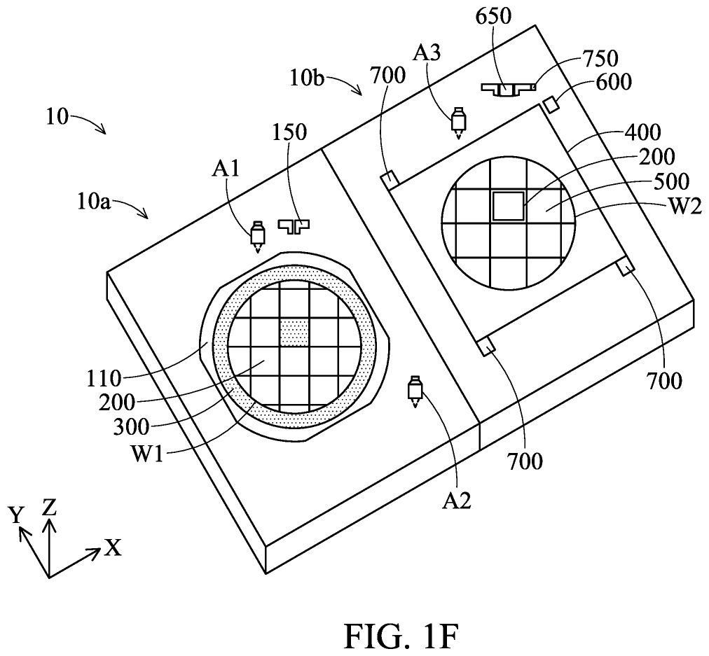

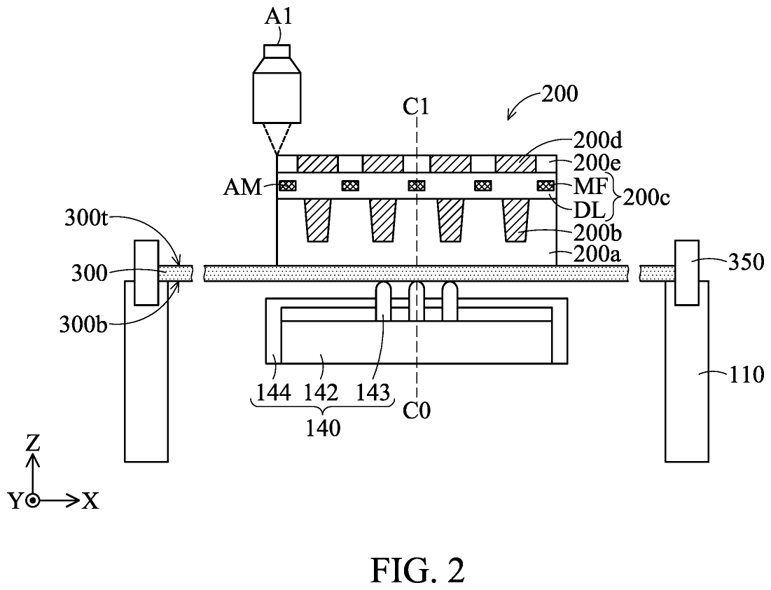

FIG. 1A to FIG. 1F are simplified perspective views showing different stages of a semiconductor die 200 in a semiconductor manufacturing apparatus 10 in accordance with some embodiments of the disclosure, in which merely some elements or components are illustrated for the purpose of simplicity and clarity. It is understood that the disclosure is not limited by the semiconductor manufacturing apparatus shown in FIG. 1A to FIG. 1F. Other elements or components (such as an ejector element, etc.) may be show in other cross-sectional views (such as FIG. 2). Additional elements or components (such as mechanical arms, motors, controllers, etc.) can be disposed within or outside of the apparatus, and the described elements or components can be replaced or modified for other embodiments.

Referring to FIG. 1A to FIG. 1F, a semiconductor manufacturing apparatus 10 is provided to perform a die lift-up operation (as shown in FIG. 1A), a die pick-up operation (as shown in FIG. 1), a flip-chip operation (as shown in FIG. 1C), a die-transfer operation (as shown in FIG. 1D), warpage measurement (as shown in FIG. 1E) and a die bonding operation (as shown in FIG. 1G). In some embodiments, the semiconductor manufacturing apparatus 10 includes a pick-up unit 10a and a bonding unit 10b adjacent to each other. A semiconductor die 200 is picked up by a collector element 150 from a wafer W1 (as shown in FIG. 1A to FIG. 1B) and then flip-chipped by the collector element 150 (as shown in FIG. 1C) in the pick-up unit 10a. After that, the flip-chipped semiconductor die 200 is transferred from the collector element 150 to a bond-head element 650 (as shown in FIG. 1D) while the warpage of the semiconductor die 200 is measured by a sensor 600. Then, an alignment process is performed to the semiconductor die 200 by an optical element A3 (as shown in FIG. 1E). Next, the semiconductor die 200 is bonded to the carrier W2 (as shown in FIG. 1F) in the bonding unit 10b. The relationships between elements and the functions of these elements are described in more detail below.

In some embodiments, in the semiconductor manufacturing apparatus 10, the pick-up unit 10a includes a frame element 110, an ejector element 140 (as shown in FIG. 2), a first optical element A1, a collector element 150 and a second optical element A2. The frame element 110 is configured to hold an adhesive film 300 adhered with a wafer W1 having multiple semiconductor dies 200. The ejector element 140 (as shown in FIG. 2) is configured to lift up a semiconductor die 200 selected from the semiconductor dies 200 of the wafer W1. The first optical element A1 is configured to check the position of the semiconductor die 200, so as to determine the process tolerance between the semiconductor die 200 and the ejector element 140 before the die lift-up operation. The collector element 150 is disposed over the frame element 110 and configured to pick up the semiconductor die 200, as shown in FIG. 1A. The second optical element A2 is configured to check the position of the semiconductor die 200, so as to determine the process tolerance between the semiconductor die 200 and the collector element 150 after the flip chip operation, as shown in FIG. 1B. For example, the first optical element A1 and the second optical element A2 may be microscopes. However, the present disclosure is not limited thereto.

In some embodiments, the bonding unit 10b includes a stage 400, a sensor 600, a bond-head element 650, a third optical element A3, a tilt mechanism 700 and a tilt sensor 750. The stage 400 is configured to hold a carrier W2. The sensor 600 is disposed adjacent to the stage 400 and configured to measure the warpage of the semiconductor die 200 which will be bonded onto the carrier W2. The bond-head element 650 is disposed over the stage 400 and configured to receive the semiconductor die 200 from the collector element 150, as shown in FIG. 1C. The third optical element A3 is configured to check the position of the semiconductor die 200, so as to determine the process tolerance between the semiconductor die 200 and the carrier W2. For example, the third optical element A3 may be a microscope. However, the present disclosure is not limited thereto.

In some embodiments, the tilt mechanism 700 is connected to the stage 400, and the tilt sensor 750 is disposed on the bond-head element 650. For example, the tilt mechanism 700 is disposed on the corners of the stage 400, other than the corner where the sensor 600 is disposed. However, the present disclosure is not limited thereto. The tilt sensor 750 is configured to detect if the stage 400 and the carrier W2 tilt relative to a horizontal plane. If it is determined that the stage 400 and the carrier W2 tilt relative to the horizontal plane, the tilt mechanism 700 operates to level the stage 400 and the carrier W2 based on the detection of the tilt sensor 750. In some embodiments, the tilt mechanism 700 and the tilt sensor 750 operate during the overall process of manufacturing the semiconductor device. In some embodiments, the tilt mechanism 700 and the tilt sensor 750 both operate before the semiconductor die 200 is bonded onto the carrier W2. Accordingly, it is more likely that the semiconductor die 200 breaks will be reduced after the leveling of the stage 400 and the carrier W2.

In some embodiments, one or more optical elements are integrated in the collector element 150 or installed onto the moving mechanism next to the collector element 150. In some embodiments, one or more optical elements are integrated in the bond-head element 650 or installed onto the moving mechanism next to the bond-head element 650.

In some embodiments, three optical elements (for example, the first optical element A1, the second optical element A2 and the third optical element A3) are included in the semiconductor manufacturing apparatus 10 to ensure an accurate die-to-carrier bonding process. Specifically, the first optical element A1 is provided in the pick-up unit 10a for checking the position of the selected die before the die lifting operation, and the third optical element A3 is provided in the bonding unit 10b for checking the position of the selected die before the bonding operation. In some embodiments, the second optical element A2 also checks the position of the selected die before the die-transfer operation. This alignment check is helpful because it may compensate for die shift during the die lift and pick-up operation, which is described in more detail below.

In some embodiments, the semiconductor manufacturing apparatus 10 shown in FIG. 1A to FIG. 1F is provided to manufacture a semiconductor device, such as a semiconductor package or a semiconductor die (e.g., a system-on-integrated circuit (SoIC), or the like). However, the present disclosure is not limited thereto. The semiconductor manufacturing apparatus 10 shown in FIG. 1A to FIG. 1F may be applied to other semiconductor devices in other embodiments.

FIG. 2 through FIG. 11 are schematic cross-sectional views showing a method of using a semiconductor manufacturing apparatus during manufacturing a semiconductor device in accordance with some embodiments of the disclosure. It is understood that the disclosure is not limited by the method described below. Additional operations can be provided before, during, and/or after the method and some of the operations described below can be replaced or eliminated, for additional embodiments of the methods.

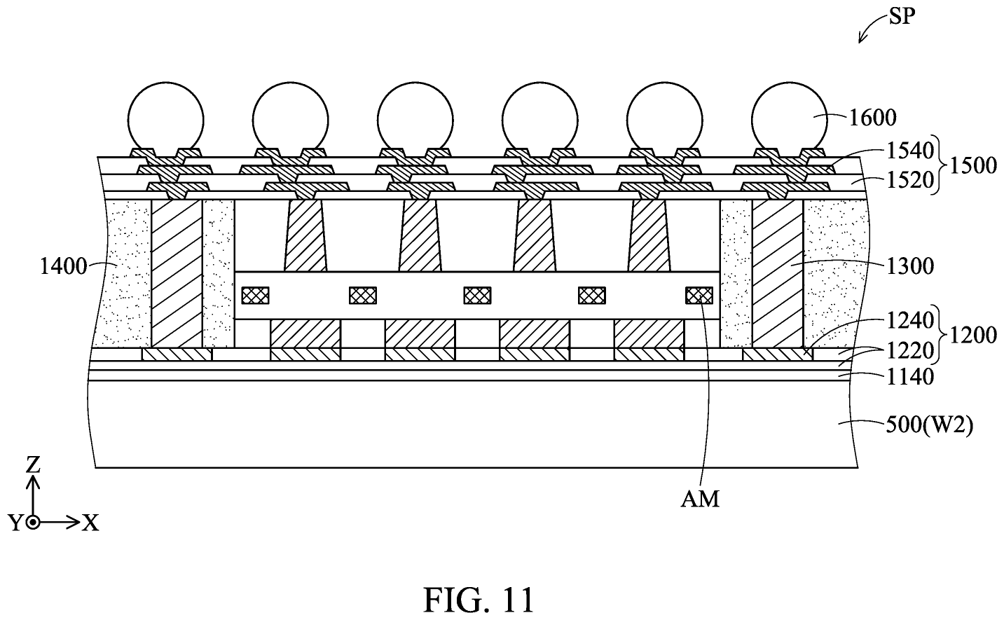

Referring to FIG. 2, in some embodiments, a method of using a semiconductor manufacturing apparatus 10 during the manufacturing process of a semiconductor package SP (as shown in FIG. 11) includes following operations. First, a wafer W1 (as shown in FIG. 1A) including semiconductor dies 200 is provided over a frame element 110, and a dicing process is performed to cut the wafer W1 into individual and separated semiconductor dies 200 along cutting lines. In one embodiment, the dicing process is a wafer dicing process including mechanical blade sawing or laser cutting. In some embodiments, before dicing/singulating, the semiconductor dies 200 included in the wafer W1 are tested for functionality and performance by probing, and only known good dies (KGDs) from the tested semiconductor dies 200 are selected and used for subsequently processing. In some embodiments, the known good dies (KGDs) from the tested semiconductor dies 200 are placed onto and adhered to an adhesive film 300 for subsequently processing. FIG. 2 illustrates only one semiconductor die 200 on the adhesive film 300 for illustrative purposes and for simplicity, but the present disclosure is not limited thereto. The adhesive film 300 is a continuous film, in some embodiments. The adhesive film 300 may be referred to as a frame tape or tape in some examples.

In addition, the semiconductor dies 200 may be arranged in an array in the wafer W1. In some embodiments, the semiconductor dies 200 are arranged in the form of a matrix, such as an N×N array or an N×M array (N, M>0, N may or may not be equal to M) along a X direction and a Y direction. The X direction and the Y direction are not the same to each other and are perpendicular to each other, for example.

As shown in FIG. 2, the semiconductor die 200 may be referred to as a semiconductor die or chip including a digital chip, analog chip or mixed signal chip. In some embodiments, the semiconductor die 200 is a logic die, a memory die, a Central Processing Unit (CPU), a Graphics Processing Unit (GPU), a Micro Electro Mechanical Systems (MEMS) die, a System on a Chip (SoC) die, or the like.

In some embodiments, the semiconductor die 200 includes a substrate 200a, through substrate vias 200b, an interconnect structure 200c, connectors 200d and a passivation layer 200e. The substrate 200a is a silicon substrate. The substrate 200a has a transistor (not shown) formed thereon, and the interconnect structure 200c is formed over the substrate 200a and electrically connected to the transistor. In some embodiments, the substrate 200a has through substrate vias 200b (also called “through silicon vias” in some examples) formed therein, and the through substrate vias 200b are not revealed from the back surface of the substrate 200a at this stage. The interconnect structure 200b includes dielectric layers DL and metal features MF embedded by the dielectric layers DL. The metal features include metal lines, metal vias, metal pads and/or metal connectors. In some embodiments, each metal feature MF includes Cu, Al, Ti, Ta, W, Ru, Co, Ni, the like, or a combination thereof. In some embodiments, each dielectric layer DL includes silicon oxide, silicon nitride, silicon oxynitride, SiOC, the like, or a combination thereof. An etching stop layer may be interposed between two adjacent dielectric layers. The dielectric layers of the interconnect structure 200b may be replaced by polymer layers or insulating layers in other embodiments.

In some embodiments, the connectors 200d are metal pillars (e.g., copper pillars). The metal pillars include Cu, W, Ni, Sn, Ti, Au, an alloy or a combination thereof, and are formed by an electroplating process. The passivation layer 200e is formed around the connectors 200d. For example, the passivation layer 200e includes a polymer material such as polybenzoxazole (PBO), polyimide, benzocyclobutene (BCB), the like, or a combination thereof. In some embodiments, the top surfaces of the connectors 200d are flushed with the top surface of the passivation layer 200e. In some embodiments, at least one alignment mark AM is formed on or in the semiconductor die 200. In some embodiments, the alignment mark AM is formed during the metal features MF are formed in the interconnect structure 200c. The alignment mark AM is square, rectangular, polygonal, strip-shaped, T-shaped, L-shaped, box-shaped, cross-shaped or any suitable shape. In some embodiments, the alignment mark is optional and may be omitted in other embodiments.

Still referring to FIG. 2, in some embodiment, the semiconductor die 200 adhered to the adhesive film 300 is placed onto the semiconductor manufacturing apparatus 10. The adhesive film 300 may be fixed onto the semiconductor manufacturing apparatus 10 through a loading element 350, where the loading element 350 may be disposed in or on the frame element 110. As shown in FIG. 2, for example, the adhesive film 300 is installed onto the semiconductor manufacturing apparatus 10 through at least partially inserting the loading element 350 into the frame element 110, where an edge of the adhesive film 300 is clamped by the loading element 350. The loading element 350 may include a fastener such as a bolt, a flange ring, or the like. In some embodiments, the loading element 350 is further capable of moving the adhesive film 300 so to align a to-be-picked up semiconductor die 200 with the ejector element 140 along a stacking Z direction.

As shown in FIG. 2, the semiconductor die 200 is disposed on (e.g., in physical contact with) a top surface 300t of the adhesive film 300, and a bottom surface 300b of the adhesive film 300 props against (e.g., in physical contact with) a top surface of the frame element 110. In some embodiments, the material of the frame element 110 may include a dielectric material, a conductive material or a combination of. For example, the frame element 110 is made of a metallic material (such as a metal or a metal alloy).

The frame element 110 may stand on a base or stage (not shown), such that an accommodating space may be confined for accommodating the ejector element 140. For example, the ejector element 140 is disposed inside the frame element 110. In other words, the ejector element 140 is under the adhesive film 300, as shown in FIG. 2, for example.

In some embodiments, the ejector element 140 includes a pin chuck 142, pins 143 and a housing 144, where the pin chuck 142 and the pins 143 are disposed inside the housing 144, as shown in FIG. 2. In some embodiments, the pins 143 are disposed on the pin chuck 142 and completely embedded in the housing 144. However, the present disclosure is not limited thereto. In other embodiments, the pins 143 are disposed on the pin chuck 142 and partially embedded in the housing 144. A motor (not shown) is configured to move up and down the pins 143 in respective with the top surface of the housing 144, so as to control movements of the pins 143 in other embodiments during the manufacture of the semiconductor package SP (referring to FIG. 11). The pins 143 may be referred to as lifting pins or pick-up pins in some examples.

In some embodiments, materials of the pin chuck 142, the pins 143 and the housing 144 each include a metallic material, such as metal or metal alloy. For example, the pin chuck 142, the pins 143 and the housing 144 independently may be made of iron (Fe), chromium (Cr), nickel (Ni), Aluminum (A1), stainless steel, combinations thereof, or the like. In some embodiments, the materials of the pin chuck 142, the pins 143, and the housing 144 may be the same. The present disclosure is not limited thereto; alternatively, the materials of the pin chuck 142, the pins 143, and the housing 144 may be different, in part or all.

In some embodiments, the ejector element 140 is positioned under the semiconductor die 200. The center CO of the ejector element 140 is substantially aligned with the center C1 of the semiconductor die 200 along the stacking Z direction, for example. In some embodiments, the semiconductor manufacturing apparatus 10 further includes a moving mechanism, where the ejector element 140 is connected to a moving mechanism (not shown) so as to control the movement of the ejector element 140. For example, the moving mechanism is configured to move the ejector element 140 vertically along the Z direction and/or horizontally along the X direction and/or the Y direction. In some embodiments, the moving mechanism may include a mechanical arm or the like.

Still referring to FIG. 2, an alignment check is performed by the first optical element A1 to determine the position of the semiconductor die 200 so as to determine whether the center C1 of the semiconductor die 200 selected from the wafer W1 is aligned with the center CO of the ejector element 140. In some embodiments, the alignment check includes detecting the intensity of light reflected by the alignment mark AM on the semiconductor die 200 using an optical element. In some embodiments, the alignment check includes detecting the edge or border of the semiconductor die 200 using a camera. In some embodiments, the edge or border of the semiconductor die 200 functions as the alignment mark for the semiconductor die 200.

In some embodiments, the position of the frame element 110 or the ejector element 140 is adjusted if the result of the alignment check of FIG. 2 shows a misalignment between the center CO of the collector element 140 and the center C1 of the semiconductor die 200. In some embodiments, the frame element 110 is connected to a moving mechanism (not shown) to control the movement of the frame element 110. For example, the moving mechanism is configured to move the frame element 110 vertically along the Z direction and/or horizontally along the X direction and/or the Y direction. In some embodiments, the moving mechanism may include a mechanical arm or the like.

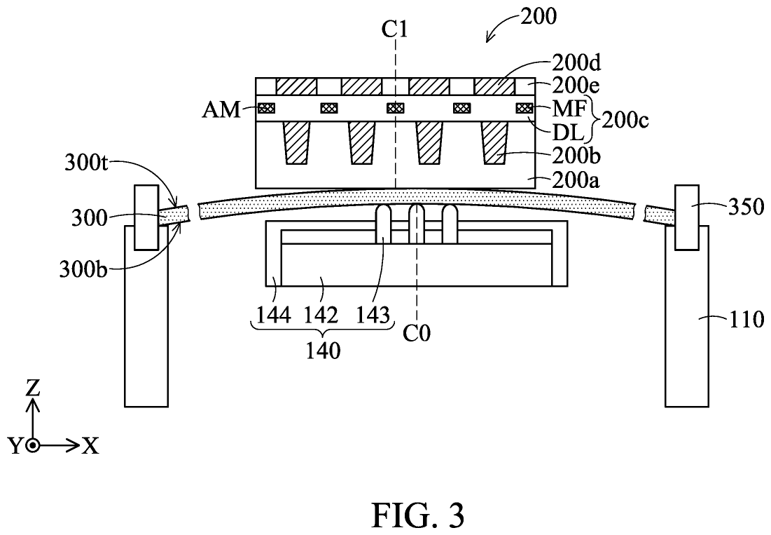

Referring to FIG. 3, after the alignment check of FIG. 2, the semiconductor die 200 is lifted up off the wafer W1 by the ejector element 140. In some embodiments, the lifting pins 143 move upwards to push up the semiconductor die 200. However, during the die lifting operation, a slight die shift may occur. The slight die shift may be caused by a bending of the adhesive film 300 or a slight warpage profile of the semiconductor die itself. In some embodiments, upon the die lifting operation, the center CO of the ejector element 140 is misaligned with the center C1 of the semiconductor die 200 along the stacking Z direction, as shown in FIG. 3.

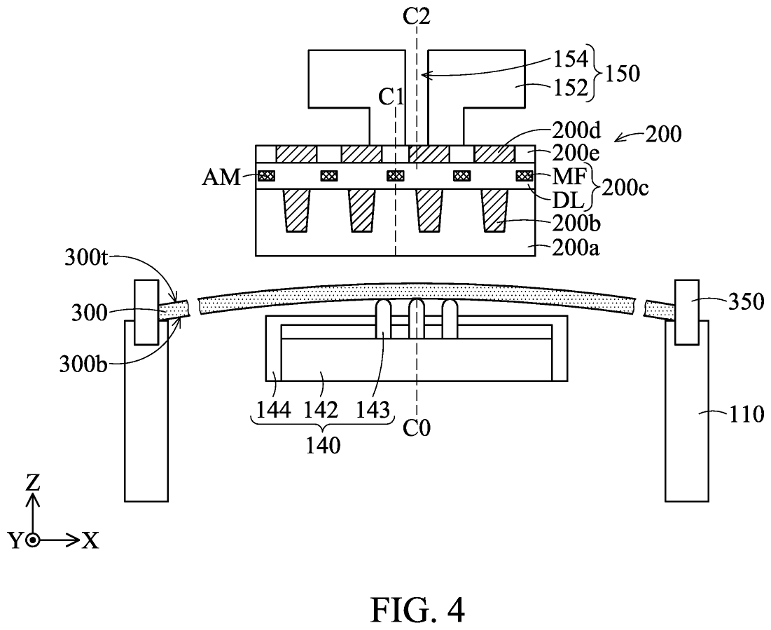

Referring to FIG. 4, a collector element 150 is provided above the semiconductor die 200. In some embodiments, due to the die shift, the center C1 of the semiconductor die 200 is misaligned with the center CO of the ejector element 140 or the center C2 of the collector element 150 along the stacking Z direction. For example, the center CO of the ejector element 140 and the center C2 of the collector element 150 may be substantially aligned with each other along the stacking Z direction, but the center C1 of the semiconductor die 200 is shifted from the center CO of the ejector element 140 and the center C2 of the collector element 150.

In some embodiments, the collector element 150 includes a body 152, at least one channel 154 embedded therein, and a vacuum element (not shown) connected to the channel 154, as shown in FIG. 4. In some embodiments, only one channel 154 penetrates through the body 152. However, the disclosure is not limited thereto. In other embodiments, multiple channels penetrate through the body 152 in other embodiments. For example, the vacuum element is configured to provide a vacuum force (e.g., generating negative pressure) to the channel 154 for picking up the semiconductor die 200. In some embodiments, the channel 154 may be referred to as a vacuum path or a vacuum channel.

In some embodiments, a material of the body 152 includes a metallic material, such as metal or metal alloy. The material of the body 152 may be the same as the materials of the pin chuck 142, the pins 143, and the housing 144. The disclosure is not limited thereto; alternatively, the material of the body 152 may be different from the materials of the pin chuck 142, the pins 143, and the housing 144, in part or all.

Still referring to FIG. 4, the semiconductor die 200 is removed (e.g., picked up) from the adhesive film 300 by the collector element 150. For example, the collector element 150 is moved down along the Z direction until the surface of the collector element 150 is in (physical) contact with the front-side surface of the semiconductor die 200, and the collector element 150 applies a vacuum force on the semiconductor die 200 through the channel 154, such that the semiconductor die 200 is held by the collector element 150 by a suction force, as shown in FIG. 4. As the semiconductor die 200 is held by the collector element 150, there is a direct contact therebetween. The collector element 150 may be referred to as a contact mode collector. However, the disclosure is not limited thereto. In other embodiments, a contactless mode collector element may be applied in other embodiments.

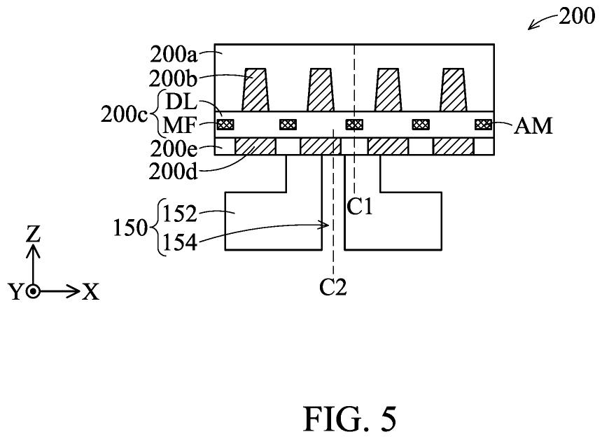

Referring to FIG. 5, the semiconductor die 200 with the collector element 150 is flip-chipped. In some embodiments, the collector element 150 and the semiconductor die 200 held therefrom are flipped (turned upside down). The back-side surface of the semiconductor die 200 is then facing up, for example.

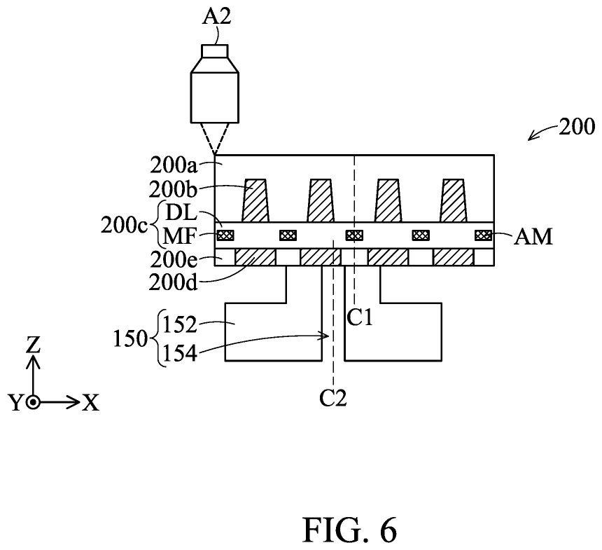

Referring to FIG. 6, an alignment check is performed by the second optical element A2 to determine the position of the semiconductor die 200 so as to determine whether the center C1 of the semiconductor die 200 is aligned with the center C2 of the collector element 150. In some embodiments, the alignment check includes detecting the intensity of light reflected by the alignment mark AM on the semiconductor die 200 using an optical element. In some embodiments, the alignment check includes detecting the edge or border of the semiconductor die 200 using a camera. In some embodiments, the edge or border of the semiconductor die 200 functions as the alignment mark for the semiconductor die 200.

In some embodiments, the semiconductor manufacturing apparatus 10 further includes a moving mechanism, where the collector element 150 is connected to the moving mechanism (not shown) to control the movement of the collector element 150. For example, the moving mechanism is configured to move the collector element 150 vertically along the Z direction and/or horizontally along the X direction and/or the Y direction. In some embodiments, the moving mechanism may include a mechanical arm or the like.

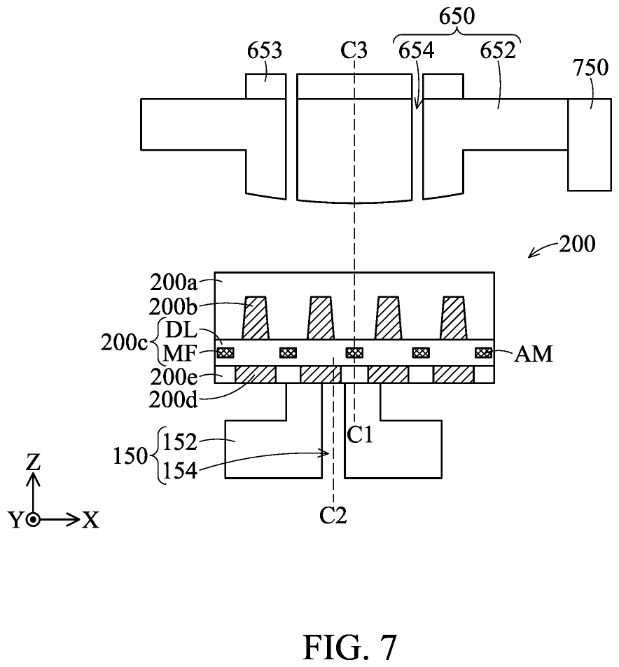

Referring to FIG. 7, after the alignment check of FIG. 6, a bond-head element 650 is provided and placed over the semiconductor die 200 for picking up the semiconductor die 200 from the collector element 150. In some embodiments, the semiconductor die 200 with the collector element 150 is transferred to a location underneath a bond-head element 650 based on the result of the alignment check of FIG. 6. Specifically, the semiconductor die 200 with the collector element 150 is transferred to the position where the center C3 of the bond-head element 650 is substantially aligned with the center C1 of the semiconductor die 200. In other words, the transfer operation compensates for die shift during the die lift-up and pick-up operations.

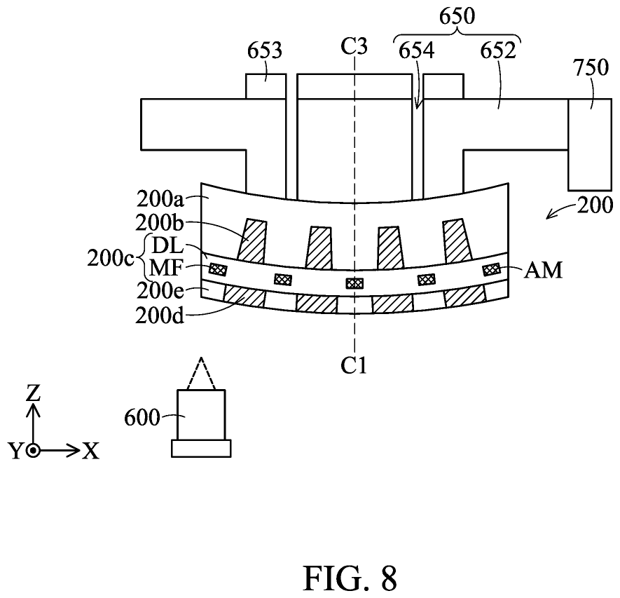

In some embodiments, the bond-head element 650 includes a body 652, at least one channel 654 embedded therein, and a vacuum element (not shown) connected to the channel 654, as shown in FIG. 7. In some embodiments, multiple channels 654 (such as two channels) penetrate through the body 652. However, the disclosure is not limited thereto. In other embodiments, only one channel penetrates through the body 652. For example, the vacuum element is configured to provide a vacuum force (e.g., generating negative pressure) to the channels 654 for picking up the semiconductor die 200. The channels 654 may be referred to as vacuum paths or a vacuum channels. In some embodiments, the bond-head element 650 has a curved surface facing to the semiconductor die 200, as shown in FIG. 8. Such curved surface is beneficial to pick up a semiconductor die 200 with a slight warpage profile in some examples. However, the disclosure is not limited thereto. In other embodiments, the bond-head element 650 has a flat surface facing to the semiconductor die 200.

In some embodiments, a material of the body 652 includes a metallic material, such as metal or metal alloy. The material of the body 652 may be the same as the material of the material of the body 152. The disclosure is not limited thereto; alternatively, the material of the body 652 may be different from the material of the body 152.

Next, referring to FIG. 8, the semiconductor die 200 is transferred from the collector element 150 to the bond-head element 650. In some embodiments the surface of the bond-head element 650 is in contact with the back-side surface of the semiconductor die 200, and the bond-head element 650 applies a vacuum force on the semiconductor die 200 through the channel 654, such that the semiconductor die 200 is held by the bond-head element 650 by direct contact. In some embodiments, after the semiconductor die 200 is securely held by the bond-head element 650 in an accurate position, the semiconductor die 200 is released by the collector element 150.

In some embodiments, the semiconductor manufacturing apparatus 10 further includes a moving mechanism, where the bond-head element 650 is connected to the moving mechanism (not shown) to control the movement of the bond-head element 650. For example, the moving mechanism is configured to move the bond-head element 650 vertically along the Z direction and/or horizontally along the X direction and/or the Y direction. In some embodiments, the moving mechanism may include a mechanical arm or the like.

In some embodiments, during the transfer operation, the position of at least one of the collector element 150 and the bond-head element 650 is adjusted based on the feedback of the alignment check of FIG. 6, until the center C3 of the bond-head element 650 is substantially aligned with the center C1 of the semiconductor die 200.

In some embodiments, the warpage of the semiconductor die 200 held by the bond-head element 650 is measured by the sensor 600. In some embodiments, the warpage of the semiconductor die 200 may be measured after the bond-head element 650 applies a vacuum force. As a result, the precise warpage of the semiconductor die 200 can be measured, which helps to optimize the bonding parameters of the subsequent bonding process. In some embodiments, the optimized bonding parameters includes the magnitude of the bonding force, the duration of the bonding process, the magnitude of the vacuum force applied by the bond-head element 650, the vacuum-off delay time, the distance that the bond-head element 650 moves, or a combination thereof. For example, is a significant warpage is measured, the magnitude of the vacuum force applied by the bond-head element 650 may be increased. However, the present disclosure is not limited thereto.

In some embodiments, the sensor 600 is movable relative to the bond-head element 650. The sensor 600 measures the height of different points on the bottom surface of the semiconductor die 200. The sensor 600 is aligned with the points being measured on the bottom surface of the semiconductor die 200. However, the present disclosure is not limited thereto. In some other embodiments, the bond-head element 650 is movable relative to the sensor 600, and therefore the sensor 600 may measure the height of different points on the bottom surface of the semiconductor die 200. To be more specific, the sensor 600 measures the location of the measured points of the semiconductor die 200 in the Z direction, and the profile of the semiconductor die 200 may be obtained. Accordingly, the warpage of the semiconductor die 200 may be determined based on the measurements performed by the sensor 600.

In some embodiments, the measured points of the semiconductor die 200 are arranged in the form of a matrix, such as an N×N array or an N×M array (N, M>0, N may or may not be equal to M) along the X direction and the Y direction. The X direction and the Y direction are not the same to each other and are perpendicular to each other, for example. For example, the measured points of the semiconductor die 200 is ranged from about 9 (e.g. 3×3) to about 900 (e.g. 30×30), such as 100 (e.g. 10×10). However, the present disclosure is not limited thereto. If there are too few points being measured, the actual profile (i.e. the warpage) of the semiconductor die 200 may not be precisely reflected in the measurement results. Conversely, if there are too many points being measured, the measurement may take too long and cost too much.

In some embodiments, the sensor 600 may emit a moiré pattern to measure the profile (e.g. the warpage) of the semiconductor die 200. As a result, a satisfactory range and time for measurement may be obtained. In some embodiments, the sensor 600 may be a laser scanning confocal microscope (LSCM). Accordingly, a high-precision measurement may be obtained.

In some embodiments, the sensor 600 may include a chromatic focal lens (e.g. Omron Chromatic Focal Lens) configured to measure different portions of the light reflected into the sensor 600, and the profile of the semiconductor die 200 may be obtained based on this measurement. To be more specific, a light source may emit a spot of white light which is divided into different lights having different wavelengths. These lights having different wavelengths would focus at different point. The sensor 600 may measure and collect these focal points and determine the height of the point where the spot of light is projected. In some embodiment, the size of the spot of light may be minimized to about 9 μm. Accordingly, high-precision measurement may be obtained.

In some embodiments, the sensor 600 may be a level sensor with at least one emitter and at least one receiver. For example, the emitter and the receiver are disposed on opposite sides of the stage 400. The receiver receives signals emitted by the emitter, and therefore the profile (e.g. the warpage) of the semiconductor die 200 may be measured. In some embodiments, a large amount of the points may be measured simultaneously. In this way, the measurement may be performed rapidly (e.g. the measured time may be reduced to not longer than about 0.12 second), saving time in the measurement process. In some embodiments, the wavelength of the signals is from about 225 nm to about 1050 nm.

In some embodiments, the top surface of the bond-head element 650 has a step structure 653 that protrudes higher than the edges of the bond-head element 650. For example, the height difference provided by the step structure 653 may help to construct a coordinate system for locating the central position of the semiconductor die 200. In some embodiments, the coordinate system may be defined by the four corners of the step structure 653. Accordingly, the bonding parameters of the following bonding process may be determined based on the coordinate system defined since the warpage of the semiconductor die 200 is precisely located. In some embodiments, the amount of warpage in the semiconductor die 200 that is detectable using the sensor 600 is about ±0.7 mm within a predetermined horizontal plane. However, the present disclosure is not limited thereto.

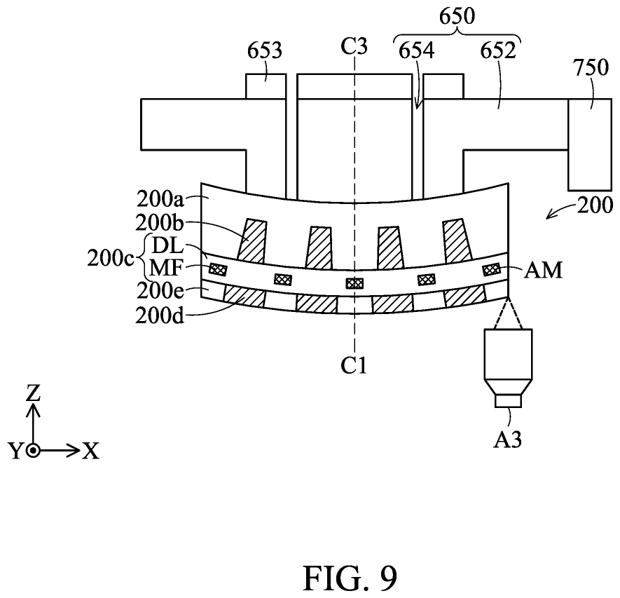

Afterwards, referring to FIG. 9, an alignment check is performed using an optical element A3 to determine the position of the semiconductor die 200, so as to determine whether the center C1 of the semiconductor die 200 is aligned with the center C3 of the bond-head element 650 or the center of the subsequently bonded region (e.g., target region 500 of the carrier W2). In some embodiments, the alignment check includes detecting the intensity of light reflected by the alignment mark AM on the semiconductor die 200 using an optical element. In some embodiments, the alignment check includes detecting the edge or border of the semiconductor die 200 using a camera. The edge or border of the semiconductor die 200 functions as the alignment mark for the semiconductor die 200.

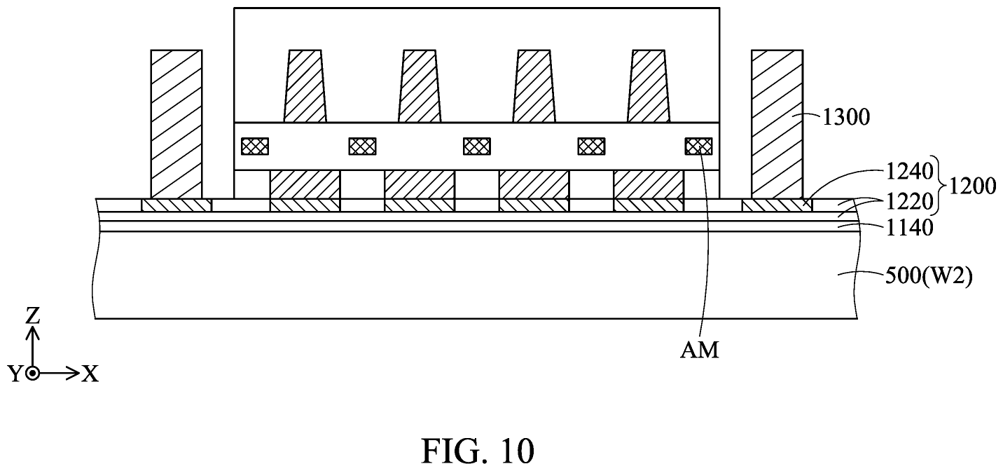

Referring to FIG. 10, a carrier W2 is provided. In some embodiments, the carrier W2 includes multiple desired regions 500 for semiconductor dies 200 to bond thereon, respectively, as shown in FIG. 1C. In one embodiment, the carrier W2 may be a glass carrier or any suitable carrier for carrying a semiconductor wafer or a reconstituted wafer for the manufacturing method of the semiconductor package. In another embodiment, the carrier W2 may be a reclaim wafer or a reconstituted wafer for the manufacturing method of the semiconductor package. For example, as the material of the carrier W2 is a silicon substrate, the carrier W2 may serve as a heat dissipating element for the semiconductor package SP. In such embodiments, the carrier W2 may further be used for warpage control.

In some other embodiments of which the carrier W2 is removed after the manufacture of the semiconductor package, the carrier W2 may further be coated with a debond layer 1140. For example, the debond layer 1140 is disposed on the carrier W2, and the material of the debond layer 1140 may be any material suitable for bonding and debonding the carrier W2 from the above layer(s) (e.g., the buffer layer) or any wafer(s) disposed thereon. In some embodiments, the debond layer 1140 may include a release layer (such as a light-to-heat conversion (“LTHC”) layer) or an adhesive layer (such as an ultra-violet curable adhesive or a heat curable adhesive layer). However, the present disclosure is not limited thereto.

In some embodiments, the position of the carrier W2 or the bond-head element 650 is adjusted if the result of the alignment check of FIG. 9 shows a misalignment between the center C3 of the bond-head element 650 and the center C1 of the semiconductor die 200. The carrier W2 is connected to a moving mechanism (not shown) to control the movement of the carrier W2. For example, the moving mechanism is configured to move the carrier W2 vertically along the Z direction and/or horizontally along the X direction and/or the Y direction. The moving mechanism may include a mechanical arm or the like. However, the present disclosure is not limited thereto.

In some embodiments, a redistribution circuit structure 1200 is formed on the carrier W2. The redistribution circuit structure 1200 may include one or more metallization patterns 1240 embedded in one or more polymer layers 1220. In some embodiments, the material of the polymer layers 1220 may include polyimide, epoxy resin, acrylic resin, phenol resin, benzocyclobutene (BCB), polybenzoxazole (PBO), or any other suitable polymer-based dielectric material, and the polymer layers 1220 may be formed by deposition. In some embodiments, the material of the metallization patterns 1240 may include aluminum, titanium, copper, nickel, tungsten, and/or alloys thereof, and the metallization patterns 1240 may be formed by electroplating or deposition. However, the present disclosure is not limited thereto.

In some embodiments, as shown in FIG. 10, through dielectric vias 1300 are formed on the redistribution circuit structure 1200. For example, the through dielectric vias 1300 are physically connected to the portions of the metallization patterns 1240 exposed by the topmost polymer layer 1220. In other words, the through dielectric vias 1300 are electrically connected to the redistribution circuit structure 1200. The through dielectric vias 1300 are referred to as through integrated fan-out (InFO) vias in some examples. In some embodiments, the through dielectric vias 1300 are formed by photolithography, plating, photoresist stripping processes or any other suitable method. In one embodiment, the material of the through dielectric vias 1300 may include a metal material such as copper or copper alloys, or the like.

Continue referring to FIG. 10, after the alignment check of FIG. 9, the semiconductor die 200 is bonded to the carrier W2 using the bond-head element 650. In some embodiments, as shown in FIG. 10, the semiconductor die 200 is placed on the redistribution circuit structure 1200 using the bond-head element 650. After the placing, the semiconductor die 200 may be released from the bond-head element 650.

In some embodiments, a bonding interface between the semiconductor die 200 and the redistribution circuit structure 1200 includes metal-to-metal bonding (e.g., copper-to-copper bonding) and dielectric-to-dielectric bonding (e.g., oxide-to-oxide bonding, oxide-to-nitride bonding, or nitride-to-nitride bonding). That is, the bonding process includes a hybrid bonding process, for example. In some embodiments, the connectors 200d of the semiconductor die 200 and the metallization patterns 1240 of the redistribution circuit structure 1200 are bonded together through a direct metal-to-metal bonding, and the passivation layer 200e of the semiconductor die 200 and the topmost polymer layer 1220 of the redistribution circuit structure 1200 are bonded together through a direct dielectric-to-dielectric bonding. In the disclosure, the bonding interface may be referred to as a hybrid bonding interface. In other words, the semiconductor die 200 is electrically connected to the redistribution circuit structure 1200, and at least some of the through dielectric vias 1300 are electrically connected to the semiconductor die 200 through the redistribution circuit structure 1200. The redistribution circuit structure 1200 may be referred to as a front-side redistribution layer of the semiconductor die 200.

Referring to FIG. 11, the semiconductor die 200 and the through dielectric vias 1300 are encapsulated in a dielectric encapsulation 1400, and a redistribution circuit structure 1500 and conductive terminals 1600 are sequentially formed on the dielectric encapsulation 1400. In some embodiments, the redistribution circuit structure 1500 is electrically connected to the semiconductor die 200 through the through dielectric vias 1300 and the redistribution circuit structure 1200. In some embodiments, some of the conductive terminals 1600 are electrically connected to the semiconductor die 200 through the redistribution circuit structure 1500, the through dielectric vias 1300 and the redistribution circuit structure 1200.

The method of forming the dielectric encapsulation 1400 may include forming a dielectric encapsulation material over the carrier W2 (e.g., on the redistribution circuit structure 1200), and then planarizing the dielectric encapsulation material until surfaces of the through substrate vias 200b of the semiconductor die 200 and surfaces of through dielectric vias 1300 are exposed. In some embodiments, the dielectric encapsulation 1400 is a molding compound formed by a molding process, and the material of the dielectric encapsulation 1400 may include epoxy or other suitable resins. For example, the dielectric encapsulation 1400 may be epoxy resin containing chemical filler.

The redistribution circuit structure 1500 may include polymer layers 1520 and metallization patterns 1540 stacked alternately. The formation and material of the polymer layers 1520 may be identical or similar to the formation and material of the polymer layers 1220 as described in FIG. 10, and the formation and material of the metallization patterns 1540 may be identical or similar to the formation and material of the metallization patterns 1240 as described in FIG. 10, and thus are not repeated herein for brevity. In certain embodiments, the topmost metallization pattern 1540 may serve as under-ball metallurgy (UBM) pads for ball mount. In some embodiments, the redistribution circuit structure 1500 may be referred to as a back-side redistribution layer of the semiconductor die 200.

In some embodiments, the conductive terminals 1600 may be placed on the UBM pads through ball placement process and/or reflow process, or other suitable forming method. In some embodiments, the conductive terminals 1600 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The material of the conductive terminals 1600, for example, may include a conductive material such as solder, copper, aluminum, gold, nickel, silver, palladium, tin, or the like, or a combination thereof. In one embodiment, the material of the conductive terminals 1600, for example, may be solder-free.

After the formation of the conductive terminals 1600, in some embodiments, a dicing process is performed to cut through the redistribution circuit structure 1500, the dielectric encapsulation 1400 and the redistribution circuit structure 1200 to obtain individual and separated semiconductor packages SP. In some embodiments, the dicing process is a wafer dicing process including mechanical blade sawing or laser cutting. The manufacture of the semiconductor package SP is thus completed. In some embodiments, after the dicing process, the carrier W2 may be detached from the redistribution circuit structure 1200 through a debonding process, where the carrier W2 and the debond layer 1140 may be removed and the redistribution circuit structure 1200 may be exposed. The semiconductor package SP may be referred to as an InFO package.

The semiconductor package SP may be further mounted with a circuit substrate, an interposer, an additional package, chips/dies or other electronic devices to form a stacked package structure through the conductive terminals 1600 and/or other additional connectors based on the design layout and the demand.

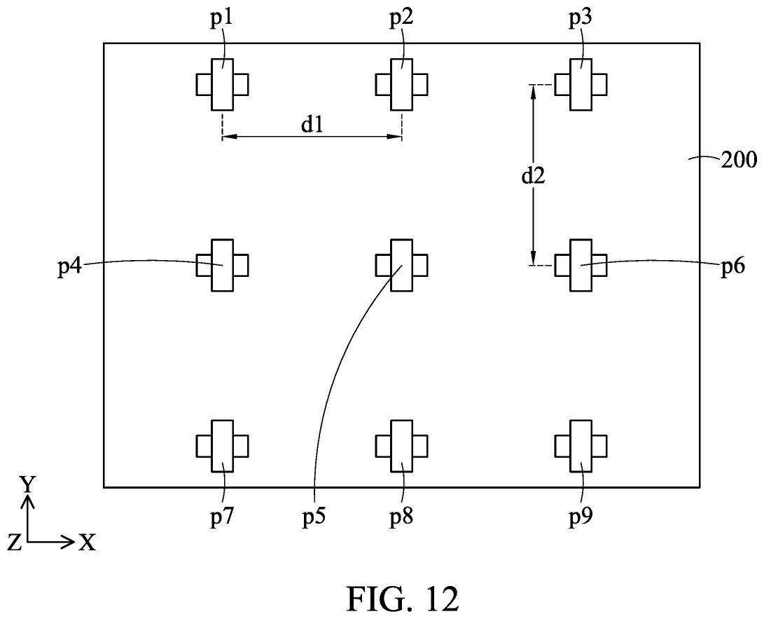

FIG. 12 illustrates a schematic view showing a plurality of measured points of the semiconductor die 200 in accordance with some embodiments of the disclosure. In some embodiments, a plurality of points p1 to p9 are the points whose heights are measured by the sensor 600. A profile of the semiconductor die 200 may be obtained based on the heights of the points p1 to p9. In some embodiments, the points p1 to p9 may be arranged in the form of a matrix, such as a 3×3 array. However, the present disclosure is not limited thereto. In some embodiments, the points p1 to p9 may be cross-shaped or have an elongated shape. The length of the points p1 to p9 may be between about 0.1 μm and about 600 μm, and the measured height of each of the points p1 to p9 may be an average height in the single point in accordance with some embodiments. As a result, the probability of obtaining an extreme value is reduced, and the precision of the warpage measurement is improved. In some embodiments, the distance d1 between the horizontally-adjacent points (for example, points p1 and p2) is measured in the X direction, and the distance d2 between the vertically-adjacent points (for example, points p3 and p6) is measured in the Y direction. In some embodiments, distances d1 and d2 are substantially greater than the length of the points p1 to p9. In some embodiments, distances d1 and d2 are substantially equal. However, the present disclosure is not limited thereto. In some other embodiments, distances d1 and d2 are different.

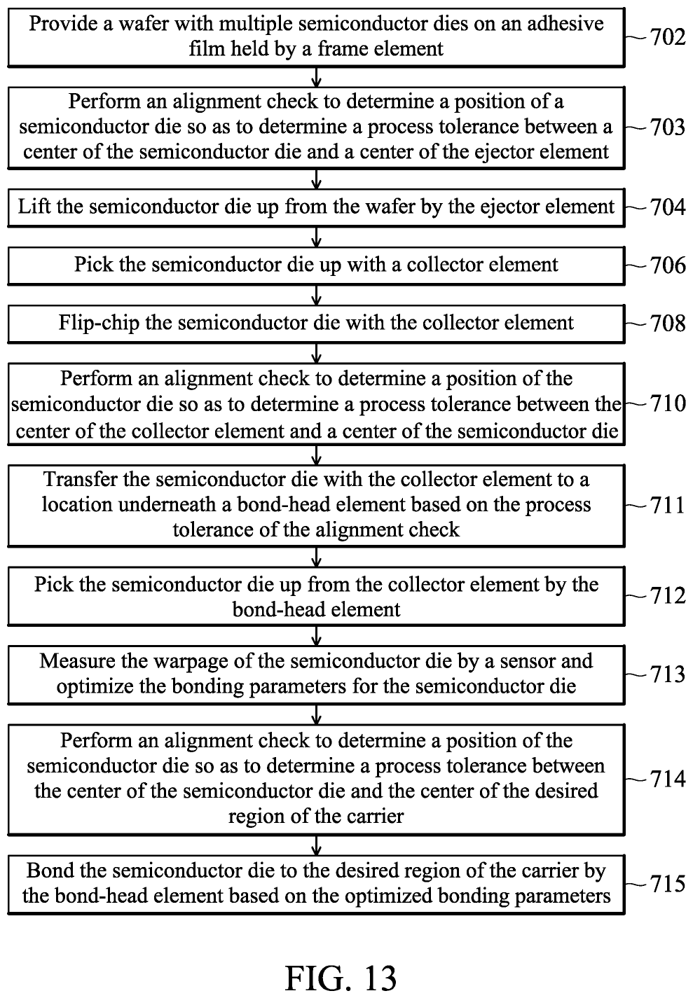

FIG. 13 illustrates a method of forming a semiconductor device in accordance with some embodiments. Although the method is illustrated or described as a series of operations or events, it should be appreciated that the method is not limited to the illustrated ordering or operations. Thus, in some embodiments, the operations may be carried out in different orders than illustrated, and/or may be carried out concurrently. Further, in some embodiments, the illustrated operations or events may be subdivided into multiple operations or events, which may be carried out at separate times or concurrently with other operations or sub-operations. In some embodiments, some illustrated operations or events may be omitted, and other operations or events may be included, despite not being depicted in the illustrations.

In operation 702, a wafer is provided with multiple semiconductor dies on the adhesive film held by the frame element. FIG. 1A and FIG. 2 illustrate different views corresponding to some embodiments of operation 702. In operation 703, an alignment check is performed to determine the position of the semiconductor die so as to determine the process tolerance between the center of the semiconductor die and the center of the ejector element. FIG. 1A and FIG. 2 illustrate different views corresponding to some embodiments of operation 703.

In operation 704, the semiconductor die is lifted up off the wafer using the ejector element. FIG. 3 illustrates a cross-sectional view corresponding to some embodiments of operation 704. In operation 706, the semiconductor die is picked up with a collector element. FIG. 1B and FIG. 4 illustrate different views corresponding to some embodiments of operation 706.

In operation 708, the semiconductor die with the collector element is flip-chipped. FIG. 1C and FIG. 5 illustrate different views corresponding to some embodiments of operation 708. In operation 710, an alignment check is performed to determine the position of the semiconductor die so as to determine the process tolerance between the center of the collector element and the center of the semiconductor die. FIG. 1C and FIG. 6 illustrate different views corresponding to some embodiments of operation 710.

In operation 711, the semiconductor die with the collector element is transferred to a location underneath a bond-head element based on the process tolerance of the alignment check in operation 710. In some embodiments, the transferring process is optimized until the center of the bond-head element is substantially aligned with the center of the semiconductor die. FIG. 1C, FIG. 1D and FIG. 7 illustrate different views corresponding to some embodiments of operation 711.

In operation 712, the semiconductor die is picked up from the collector element using the bond-head element. FIG. 1D and FIG. 8 illustrate different views corresponding to some embodiments of operation 712. In operation 713, the warpage of the semiconductor die is measured by a sensor for optimizing the bonding parameters for the semiconductor die. FIG. 1D and FIG. 8 illustrate different views corresponding to some embodiments of operation 713.

In operation 714, an alignment check is performed to determine a position of the semiconductor die so as to determine the process tolerance between the center of the semiconductor die and the center of the desired region of the carrier. FIG. 9 illustrates a cross-sectional view corresponding to some embodiments of operation 714. In operation 715, the semiconductor die is bonded to the desired region of the carrier using the bond-head element. FIG. 1E and FIG. 10 to FIG. 11 illustrate different views corresponding to some embodiments of operation 715.

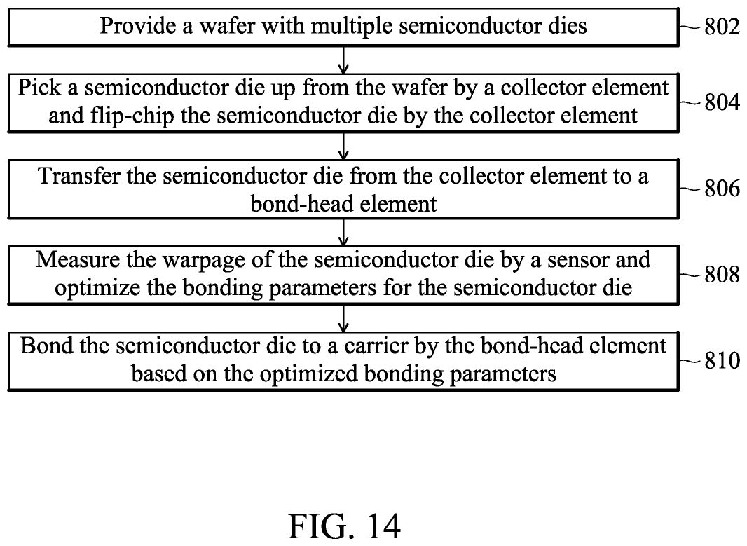

FIG. 14 illustrates a method of forming a semiconductor device in accordance with some embodiments. Although the method is illustrated and/or described as a series of operations or events, it should be appreciated that the method is not limited to the illustrated ordering or operations. Thus, in some embodiments, the operations may be carried out in different orders than illustrated, and/or may be carried out concurrently. Further, in some embodiments, the illustrated operations or events may be subdivided into multiple operations or events, which may be carried out at separate times or concurrently with other operations or sub-operations. In some embodiments, some illustrated operations or events may be omitted, and other operations or events that are not depicted in the illustrations may be included.

In operation 802, a wafer is provided with multiple semiconductor dies. FIG. 1A and FIG. 2 illustrate different views corresponding to some embodiments of operation 802. In operation 804, a semiconductor die is picked up from the wafer by a collector element and flip-chipped by the collector element. In some embodiments, before the picking-up and flip-chipping operations in operation 804, the semiconductor die is lifted up of the wafer by the ejector element. FIG. 1A to FIG. 1B and FIG. 3 to FIG. 5 illustrate different views corresponding to some embodiments of operation 804.

In operation 806, the semiconductor die is transferred from the collector element to a bond-head element. FIG. 1C to FIG. 1D and FIG. 6 to FIG. 7 illustrate different views corresponding to some embodiments of operation 806. In operation 808, the semiconductor die is transferred from the collector element to a bond-head element. Operation 806 is performed prior to the transfer operation in operation 808. In some embodiments, the warpage of the semiconductor die is measured by a sensor for optimizing the bonding parameters for the semiconductor die. FIG. 1D and FIG. 8 illustrate different views corresponding to some embodiments of operation 808.

In operation 810, the semiconductor die is bonded to a carrier using the bond-head element based on the optimized bonding parameters in operation 808. FIG. 1E to FIG. 1F and FIG. 9 to FIG. 11 illustrate different views corresponding to some embodiments of operation 810.

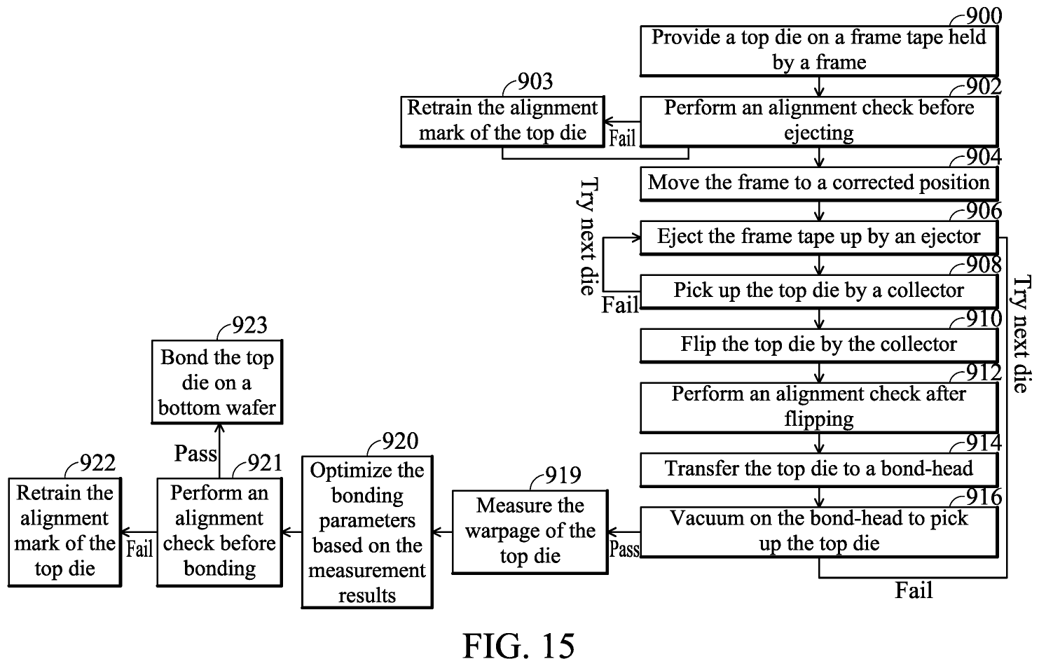

FIG. 15 illustrates a method of forming a semiconductor device in accordance with some embodiments. Although the method is illustrated and/or described as a series of operations or events, it should be appreciated that the method is not limited to the illustrated ordering or operations. Thus, in some embodiments, the operations may be carried out in different orders than illustrated, and/or may be carried out concurrently. Further, in some embodiments, the illustrated operations or events may be subdivided into multiple operations or events, which may be carried out at separate times or concurrently with other operations or sub-operations. In some embodiments, some illustrated operations or events may be omitted, and other operations or events may be included although they are not depicted in the illustrations.

Operation 900 is implemented to provide a top die on a frame tape held by a frame. Operation 902 is implemented to perform an alignment check before ejecting. In some embodiments, the result of the alignment check is evaluated to determine whether the result passes or fails the specification or standard. If the result passes the specification or standard, operation 904 is implemented to move a frame to a corrected position. If the result fails the specification or standard, operation 903 is implemented to retrain the alignment mark of the top die, and operation 902 is then implemented again.

Operation 906 is implemented to eject the frame tape up by an ejector. Next, operation 908 is implemented to pick up the top die by a collector. In some embodiments, the vacuum performance is evaluated to determine whether the vacuum passes or fails the specification or standard. If the vacuum passes the specification or standard, operation 910 is implemented to flip the top die by the collector. If the vacuum fails the specification or standard, operation 906 is then implemented to try next die.

Then, operation 910 is implemented to flip the top die by the collector. Operation 912 is implemented to perform a top die alignment after flipping. Operation 914 is implemented to transfer the top die to a bond-head. Operation 916 is implemented to vacuum on the bond-head to pick up the top die. In some embodiments, the vacuum performance is evaluated to determine whether the vacuum passes or fails the specification or standard. If the vacuum passes the specification or standard, operation 919 is implemented to measure the warpage of the top die. If the vacuum fails the specification or standard, operation 906 is then implemented to try next die.

Afterwards, operation 920 is implemented to optimize the bonding parameters based on the measurement results. Operation 921 is implemented to perform a top die alignment before bonding. In some embodiments, the result of the alignment check is evaluated to determine whether the result passes or fails the specification or standard. If the result passes the specification or standard, operation 923 is implemented to bond the top die on a bottom wafer. If the result fails the specification or standard, operation 922 is implemented to retrain the alignment mark of the top die, and operation 921 is then implemented again.

As set forth above, the present disclosure provides a method for forming a semiconductor device that includes measuring the warpage of the semiconductor die by a sensor after the semiconductor die is transferred to a bond-head element. Such warpage measurement provides data to optimize the bonding parameters, so that the subsequent bonding process may be performed accurately and therefore the yield may be improved. In addition, a tilt sensor and a tilt mechanism are also disposed in the semiconductor manufacturing apparatus for detecting if the stage and the carrier tilts and leveling the stage and the carrier, so as to reduce improper bonding between the semiconductor die and the carrier.

In some embodiments, a method for forming a semiconductor device is provided, and the method includes providing a wafer with multiple semiconductor dies on the adhesive film held by the frame element. The method also includes lifting a semiconductor die up from the wafer using an ejector element. The method includes picking the semiconductor die up with a collector element. The method further includes flip-chipping the semiconductor die with the collector element, and picking up the semiconductor die from the collector element using the bond-head element. In addition, the method includes measuring the warpage of the semiconductor die on the bond-head element using a sensor. The semiconductor die is then bonded to a carrier using the bond-head element.

In some embodiments, a method for forming a semiconductor device is provided, and the method includes holding a semiconductor die with a bond-head element. The method includes measuring the warpage of the semiconductor die on the bond-head element using a sensor. The method also includes optimizing the parameters for bonding the semiconductor die based on the measured warpage of the semiconductor die. The method further includes bonding the semiconductor die to a carrier using the bond-head element and the optimized parameters.

In some embodiments, a semiconductor manufacturing apparatus is provided, and the semiconductor manufacturing apparatus includes a pick-up unit and a bonding unit, disposed adjacent to the pick-up unit. The pick-up unit includes: a frame element configured to hold an adhesive film adhered with a semiconductor die; an ejector element configured to lift up the semiconductor die; and a collector element disposed over the frame element and configured to pick up the semiconductor die. The bonding unit includes: a stage configured to hold a carrier; a bond-head element configured to receive and hold the semiconductor die from the collector element; and a sensor disposed adjacent to the stage and configured to measure the warpage of the semiconductor die on the bond-head element.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device, comprising:
providing a wafer with multiple semiconductor dies on an adhesive film held by a frame element;
lifting a semiconductor die up from the wafer using an ejector element;
picking the semiconductor die up with a collector element;
flip-chipping the semiconductor die with the collector element;
picking up the semiconductor die from the collector element using a bond-head element;
performing a measurement of a warpage of the semiconductor die on the bond-head element using a sensor; and
bonding the semiconductor die to a carrier using the bond-head element.

2. The method as claimed in claim 1, further comprising:
optimizing parameters of bonding the semiconductor die based on the measured warpage of the semiconductor die.

3. The method as claimed in claim 1, further comprising:
performing an alignment check to determine a position of the semiconductor die between a center of the bond-head element and a center of the semiconductor die.

4. The method as claimed in claim 3, wherein the measurement to the warpage of the semiconductor die is performed prior to the alignment check.

5. The method as claimed in claim 1, wherein performing the measurement to the warpage of the semiconductor die further comprises moving the senor relative to the semiconductor die.

6. The method as claimed in claim 1, wherein performing the measurement to the warpage of the semiconductor die further comprises measuring heights of a plurality of points on the semiconductor die, and the number of the points is between about 9 to about 900.

7. The method as claimed in claim 6, wherein the points each have an elongated shape.

8. The method as claimed in claim 7, wherein a length of each of the points is between about 0.1 μm to about 600 μm.

9. The method as claimed in claim 1, further comprising applying a vacuum force using the bond-head element to hold the semiconductor die, wherein applying the vacuum force is prior to the measurement to the warpage of the semiconductor die.

10. The method as claimed in claim 1, further comprising:
detecting if the carrier tilts from a horizontal plane by a tilt sensor on the bond-head element; and
leveling the carrier by a tilt mechanism if the carrier tilts from the horizontal plane.

11. A method for forming a semiconductor device, comprising:
holding a semiconductor die using a bond-head element;
performing a measurement of a warpage of the semiconductor die on the bond-head element using a sensor;
optimizing parameters of bonding the semiconductor die based on the measured warpage of the semiconductor die; and
bonding the semiconductor die to a carrier using the bond-head element based on the optimized parameters.

12. The method as claimed in claim 11, wherein performing the measurement to the warpage of the semiconductor die comprises measuring heights of a plurality of points on the semiconductor die, and the points is arranged in the form of matrix.

13. The method as claimed in claim 12, wherein performing the measurement to the warpage of the semiconductor die comprises moving either of the bond-head element or the sensor so as to align the sensor with the points on the semiconductor die.

14. The method as claimed in claim 11, wherein performing the measurement to the warpage of the semiconductor die comprises:
defining a coordinate system based on a step structure of the bond-head element; and
locating the warpage of the semiconductor die on the defined coordinate system.

15. A semiconductor manufacturing apparatus, comprising:
a pick-up unit, comprising:
a frame element configured to hold an adhesive film adhered with a semiconductor die;
an ejector element configured to lift up the semiconductor die; and
a collector element disposed over the frame element and configured to pick up the semiconductor die; and
a bonding unit, disposed adjacent to the pick-up unit, comprising:
a stage configured to hold a carrier;
a bond-head element configured to receive and hold the semiconductor die from the collector element; and
a sensor disposed adjacent to the stage and configured to measure the warpage of the semiconductor die on the bond-head element.

16. The semiconductor manufacturing apparatus as claimed in claim 15, wherein the sensor is movable relative to the bond-head element.

17. The semiconductor manufacturing apparatus as claimed in claim 15, wherein the pick-up unit further comprises a first optical element configured to determine a process tolerance between the semiconductor die and the ejector element.

18. The semiconductor manufacturing apparatus as claimed in claim 15, wherein the pick-up unit further comprises a second optical element configured to determine a process tolerance between the semiconductor die and the collector element.

19. The semiconductor manufacturing apparatus as claimed in claim 15, wherein the bonding unit further comprises a third optical element configured to determine a process tolerance between the semiconductor die and the carrier.

20. The semiconductor manufacturing apparatus as claimed in claim 15, further comprising:
a tilt sensor disposed on the bond-head element and configured to detect whether the stage tilts; and
a tilt mechanism connected to the stage and configured to level the stage.
